(19) United States
(12) Patent Application Publication
(10) Pub. No.: US 2025/0185242 A1
(43) Pub. Date: Jun. 5, 2025

(54) METHOD FOR MANUFACTURING AN INTEGRATED CIRCUIT AND CORRESPONDING INTEGRATED CIRCUIT

(71) Applicant: STMicroelectronics International N.V., Geneva (CH)

(72) Inventors: Carlos Augusto SUAREZ SEGOVIA, Seyssinet-Pariset (FR); Simon JEANNOT, Grenoble (FR); Catherine MARTINELLI, Meylan (FR); Nadia MIRIDI, Auriol (FR)

(73) Assignee: STMicroelectronics International N.V., Geneva (CH)

(21) Appl. No.: 18/959,835

(22) Filed: Nov. 26, 2024

(30) Foreign Application Priority Data
Dec. 1, 2023 (FR) 2313460

(51) Int. Cl. H10B 41/35

(52) U.S. Cl. CPC H10B 41/35

(57) ABSTRACT

Lateral isolation regions are formed in a semiconductor substrate to delimiting active regions of the semiconductor substrate. A trench is then etched extending vertically in depth in the substrate through the lateral isolation regions and the active regions. The formation of the lateral isolation regions is configured to provide, at the location of where the etching of the trench is to be performed, enlarged portions of the lateral isolation regions delimiting thinned portions of the active regions. As a result, the bottom of the trench has a form having variations in depth with low portions facing the location of the trench that passes through the lateral isolation regions, and high portions facing the location of the trench that passes through the active regions.

### PRIORITY CLAIM

This application claims the priority benefit of French Application for Patent No. 2313460, filed on Dec. 1, 2023, the content of which is hereby incorporated by reference in its entirety to the maximum extent allowable by law.

### TECHNICAL FIELD

Embodiments and implementations relate to integrated circuits and, in particular, to integrated circuits including an implementation of a trench extending vertically in depth in the substrate, such as integrated circuits incorporating a vertical-gate buried transistor, for example transistors for access to non-volatile memory cells.

### BACKGROUND

FIGS. 1A, 1B and 1C illustrate an example of a memory plane incorporating memory cells CEL1, CEL2 in a non-volatile memory technology. The memory cells CEL1, CEL2 are provided with a floating-gate state transistor TE in series with a vertical-gate buried access transistor TA.

FIG. 1A illustrates the arrangement of the memory cells in a plan view of the memory plane (in the semiconductor manufacturing art, this is usually designated as the Front End Of Line (FEOL) phase).

FIG. 1B illustrates a view in cross section in the plane BB of FIG. 1A, the plane BB passing through gate regions of the state transistors and the vertical gate region in width.

FIG. 1C illustrates a view in cross section in the plane CC of FIG. 1A, passing through the vertical gate region in length.

Briefly, the state transistor TE makes it possible to store a charge representing a binary data item in its floating gate FG, and the access transistor TA makes it possible to selectively access the memory cell CEL1, CEL2 in write and read mode, for example.

Furthermore, to access the memory cells CEL1, CEL2, the drain region D of the state transistor TE is typically connected to a bit line, while the source region of the access transistor TA is accessed by a region NISO implanted in depth in the substrate, which can be referred to as the source plane.

Typically, the bottom of the vertical gate TRG of the access transistor TA does not come into contact with the source plane NISO in-depth, and a source region Simp (also referred to as the source implant) is implanted in the substrate between the bottom of the vertical gate TRG and the source plane. The implantation of the source region Simp is performed from the bottom of the trench that was etched to form the vertical gate TRG. The source implant Simp is thus designed to provide electrical continuity with the source plane NISO.

It has been noted by the inventors that a limitation of the performance and a loss of efficiency of this non-volatile memory technology could be related to a low access current in the memory cell, caused by a high resistance of the access transistor TA. This is because, if the trench including the vertical gate TRG has an effective depth p11 that is less than a nominal depth p10, then it is possible that the electrical continuity between the source implant Simp and the source plane NISO may be poorly established, which causes said increase in the resistance of the access transistor TA.

The inventors have furthermore established a correlation between the increase in the resistance of the access transistor TA and the depth of lateral isolation regions STI, typically shallow isolation trenches. This is because the trench containing the vertical gate is etched, in particular, in lateral isolation regions STI at the surface of the substrate, typically made of silicon oxide, and then in the substrate typically made of monocrystalline silica. However, the etch rate of the trench is much more rapid in silicon oxide than in the monocrystalline substrate.

Consequently, for equal etching times, the depth of the trench p11 will be less if the depth of the lateral isolation region p21 is smaller, and the depth of the trench p10 will be greater (or at a nominal value) if the depth of the lateral isolation region p20 is greater (or at a nominal value).

Finally, a depth p21 of the lateral isolation regions STI smaller than a nominal depth p20 provided in the design may be caused by a phenomenon of stoppage of the etching of the shallow trenches STI, usually referred to in the art as an STI etch stop.

This undesirable phenomenon is briefly caused by a saturation of etched (reactive) material or of products of the etching reaction, in an excessively narrow etched space w21. This phenomenon may occur with so-called random variations in the manufacturing method, in particular with regard to the position on the semiconductor wafer, and is difficult to control.

### SUMMARY

Embodiments and implementations of the aspects defined below propose forming lateral isolation regions including enlarged portions under the trench, and thinned portions outside the trench.

In other words, it is proposed to form active regions with a double width, the active regions including thinned portions under the trench, and enlarged portions outside the trench, given that the lateral isolation regions delimit the active regions in a superficial region of the semiconductor substrate.

It should be noted in particular that the solutions proposed in the embodiments and implementations defined below advantageously do not make provision for modifying the chemical reaction used in the etching of the shallow isolation trenches STI, which would be expensive and difficult to put into practice in existing methods, or for modifying overall the nominal width w20 of the lateral isolation regions, which would affect overall the performances of the active regions, or for increasing the trench etching time, which would also give rise to an impact on other formations of devices using the same step of etching the vertical-gate buried transistor.

Thus, according to one aspect, a method is proposed for manufacturing an integrated circuit, comprising forming lateral isolation regions, for example shallow isolation trenches, that delimit active regions in a semiconductor substrate, and etching a trench extending vertically in depth in the substrate through said lateral isolation regions and said active regions. The formation of the lateral isolation regions is configured to form, at the location of said etching of the trench, enlarged portions of the lateral isolation regions delimiting thinned portions of the active regions.

In consequence of this particular arrangement of enlarged portions of the lateral isolation regions delimiting thinned portions of the active regions at the location of said etching of the trench, the bottom of the trench will have a form having variations in depth with low portions facing the lateral isolation regions thus etched, and high portions facing the active regions thus etched.

The low portions reach a sufficient depth to ensure electrical continuity between the source implant and the source plane.

Thus, implementing the method according to this aspect in the context of a manufacture of a memory having a vertical-gate buried access transistor in the trench improves the performance and efficiency of the memory, in particular by reducing the resistance of the access transistor.

According to one embodiment, said formation of the lateral isolation regions delimits the active regions extending in length in a first direction while said trench extends in length in a second direction perpendicular to the first direction, said enlarged and thinned portions being larger and respectively smaller in width in the second direction at the location of the etching of the trench than outside the location of the etching of the trench.

In one embodiment, the formation of the lateral isolation regions comprises a production of a volume of dielectric material, for example of silicon oxide, in the substrate, while the active regions of the substrate are produced from monocrystalline semiconductor material, for example from silicon; the dynamics of the etching of the trench being faster in the dielectric material than in the monocrystalline semiconductor material.

According to one embodiment, a gate of a vertical-gate buried access transistor is formed in said trench etched in depth in the substrate, and a stack of a floating gate and of a control gate of a state transistor at least partly covering said active regions in the vicinity of the trench is formed.

According to another aspect, an integrated circuit is also proposed comprising lateral isolation regions delimiting active regions in a semiconductor substrate, and a component arranged in a trench extending vertically in depth in the substrate through said lateral isolation regions and said active regions. The bottom of the trench has a form having variations in depth with low portions facing the location of the trench that passes through the lateral isolation regions, and high portions facing the location of the trench that passes through the active regions.

For example, the variations in depth have an amplitude greater than 50 nm.

According to one embodiment, the lateral isolation regions delimit the active regions extending in length in a first direction while said trench extends in length in a second direction perpendicular to the first direction, the variations in depth in the bottom of the trench having successive alternations in the direction of the second direction.

In one embodiment, said low portions are located in planes directed by the vertical direction and the first direction and pass through the lateral isolation regions, and said high portions are located in planes directed by the vertical direction and the first direction and pass through the active regions.

According to one embodiment, the integrated circuit includes a vertical-gate buried access transistor, the vertical gate being the component arranged in said trench, and a state transistor including a stack of a floating gate and of a control gate at least partly covering said active regions in the vicinity of the trench.

According to one embodiment, the bottom of the trench has an appearance, in the second direction, that is substantially hypotrochoidal (i.e., with a shortened trochoid).

According to another aspect, a semiconductor device is also proposed comprising lateral isolation regions delimiting active regions in a semiconductor substrate, wherein enlarged portions of the lateral isolation regions delimit thinned portions of the active regions.

The semiconductor device according to this aspect corresponds, for example, to the integrated circuit in the course of manufacture in the method defined above, before said trench is etched.

Thus, according to one embodiment, the semiconductor device is able to be fashioned by etching a trench as defined above. In other words, in particular a trench extending vertically in depth in the substrate through said lateral isolation regions and said active regions, at the location of the enlarged portions of the lateral isolation regions delimiting thinned portions of the active regions.

### BRIEF DESCRIPTION OF THE DRAWINGS

Other advantages and features of the invention will appear upon examining the detailed description of non-limiting implementations and embodiments, and from the appended drawings, on which, figures:

FIGS. 1A, 1B and 1C illustrate an example of a memory plane incorporating memory cells in a non-volatile memory technology;

FIGS. 2A, 2B, 2C and 2D illustrate the result of a step of forming lateral isolation regions in semiconductor substrate of a method for manufacturing an integrated circuit;

FIGS. 3A, 3B, 3C and 3D illustrate the memory plane during the start of a step of etching a trench extending in depth in the substrate of said method for manufacturing an integrated circuit;

FIGS. 4A, 4B, 4C and 4D illustrate the memory plane at the end of the step of etching the trench extending in depth in the substrate of said method for manufacturing an integrated circuit;

FIGS. 5A, 5B, 5C and 5D illustrate the memory plane at the end of a formation of a gate structure in the trench extending in depth in the substrate of said method for manufacturing an integrated circuit; and

FIGS. 6A, 6B, 6C and 6D illustrate the memory plane at the end of steps finalizing the formation of memory cells, in particular forming state transistors, of said method for manufacturing an integrated circuit.

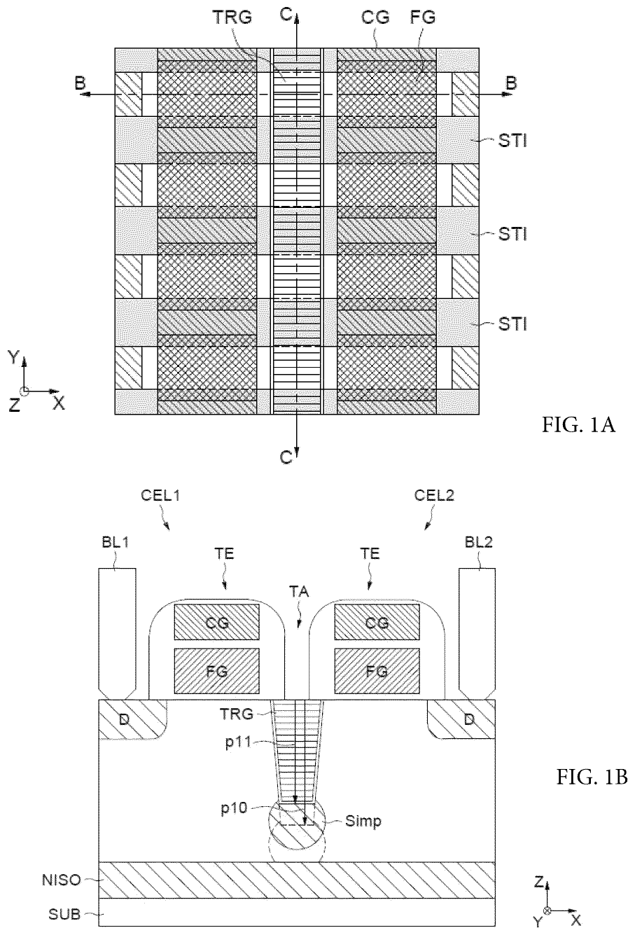

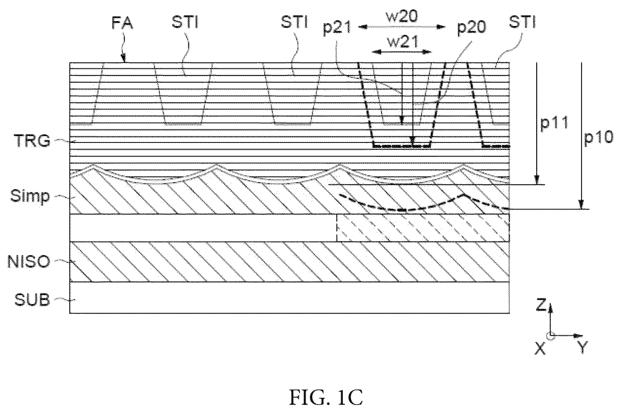

### DETAILED DESCRIPTION

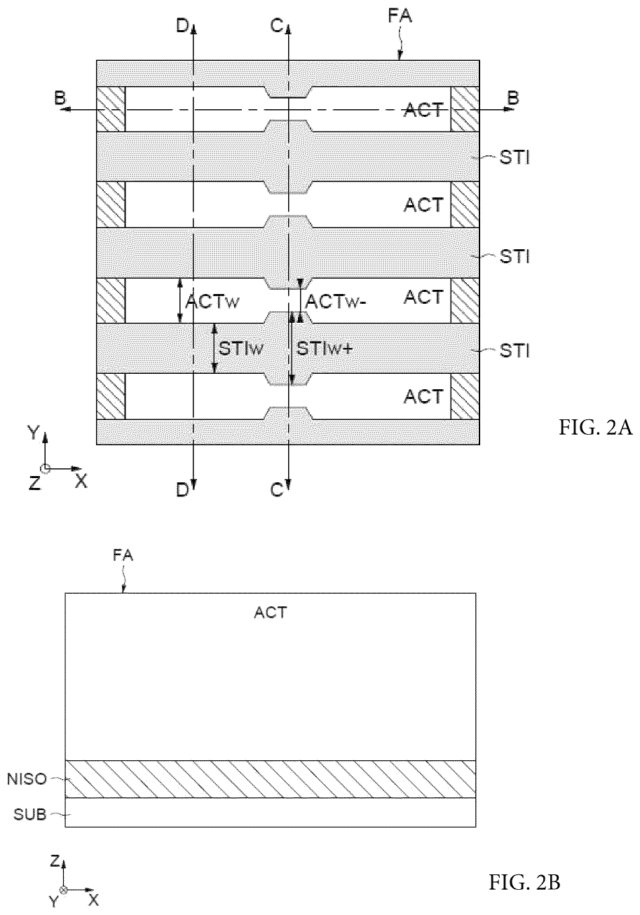

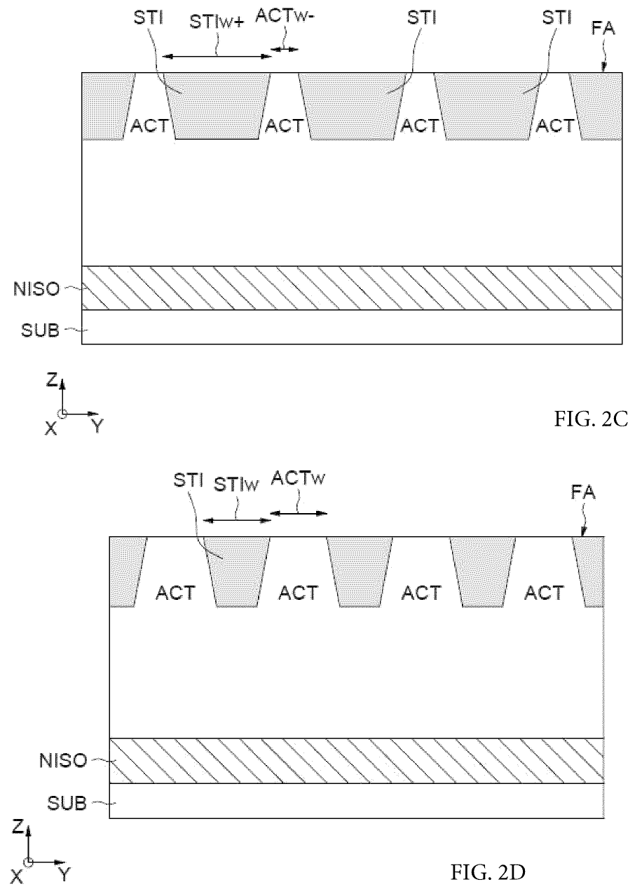

FIGS. 2A, 2B, 2C and 2D illustrate the result of a step of forming lateral isolation regions STI in semiconductor substrate SUB of a method for manufacturing an integrated circuit, particularly in a memory plane of the integrated circuit, intended to include the cells.

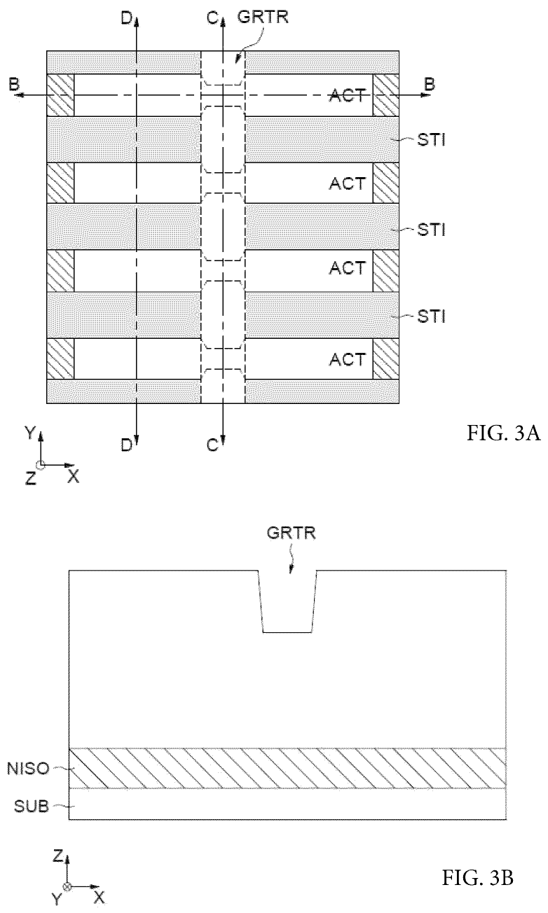

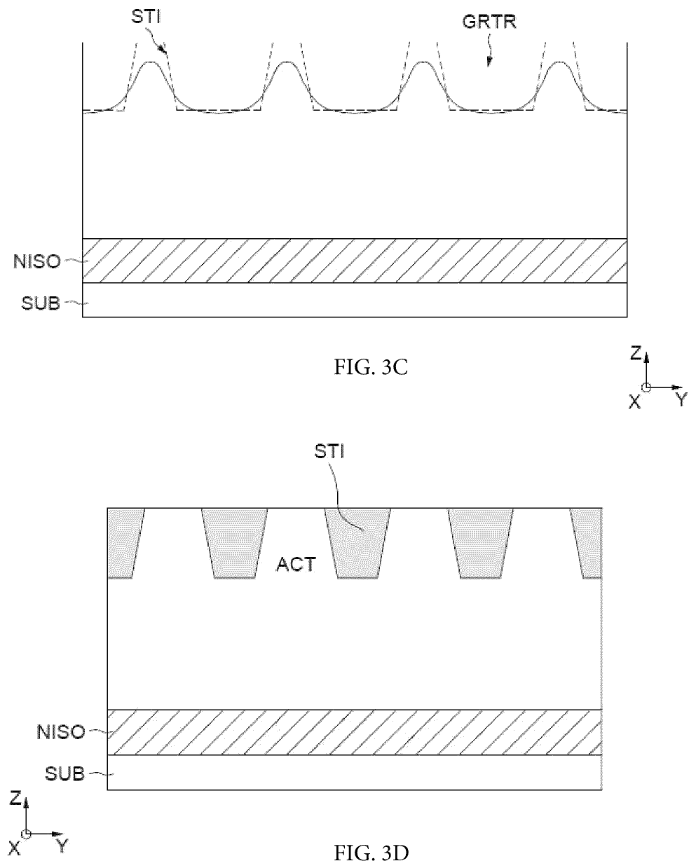

An orthogonal reference frame XYZ is defined common to FIGS. 2A-2D, as well as to FIGS. 3A-3D, 4A-4D, 5A-5D, 6A-6D described below.

The first direction X and the second direction Y are located in the plane of the front face FA (see below), and the third direction Z is vertical.

FIG. 2A illustrates a plan view of the front face FA of the substrate SUB (see below).

FIG. 2B illustrates a view in cross section in the plane BB of FIG. 2A. The plane BB directed by the first direction X and the vertical direction Z is positioned in the length of the active region ACT (see below).

FIG. 2C illustrates a view in cross section in the plane CC of FIG. 2A. The plane CC is directed by the second direction Y and the vertical direction Z, and is positioned through lateral isolation regions STI having an enlarged width or portion STIw+ (relative to a nominal width as discussed below) and active regions ACT having a thinned width or portion ACTw− (relative to a nominal width as discussed below).

FIG. 2D illustrates a view in cross section in the plane DD in FIG. 2A. The plane DD is directed by the second direction Y and the vertical direction Z, and is positioned through the lateral isolation regions STI having a nominal width STIw and active regions ACT having a nominal width ACTw (see below).

The front face FA of the substrate SUB is the face as from which the devices of the semiconductor part are produced by the Front End Of Line (FEOL) phase of manufacturing.

Before or after the lateral isolation regions STL were formed, a region NISO implanted in depth in the semiconductor substrate SUB was formed. The region NISO implanted in depth, of a dopant type opposite to the type of dopants of the substrate SUB, can offer the function of memory-cell source plane. Conventionally, almost no other step is implemented prior to the formation of the lateral isolation regions STI.

The lateral isolation regions STI are formed in a superficial region of the semiconductor substrate SUB from the front face FA (i.e., a shallow region, for example of substantially 250 nm or between 150 nm and 350 nm).

The lateral isolation regions STI are obtained by a technique of shallow isolation trenches. In other words, they are obtained by etching shallow trenches (substantially 200 nm to 250 nm) open in the superficial region of the substrate SUB, and by filling the trenches with a dielectric material, typically silicon oxide.

The lateral isolation regions STI delimit active regions ACT of the substrate, which extend in length in the first direction X.

The step of forming the lateral isolation regions STI is configured to form enlarged portions STIw+ of the lateral isolation regions STI delimiting thinned portions ACTw− of the active regions ACT.

The enlarged portions STIw+ of the lateral isolation regions STI are positioned at the location of the subsequent etching GRTR of a trench extending vertically in depth in the substrate SUB (see, also, FIGS. 3A-3D).

Elsewhere, such as outside the location of the subsequent etching GRTR, the lateral isolation regions STI of this part of the semiconductor substrate have a nominal width STIw so as to define active regions ACT having a nominal width ACTw.

Thus, the enlarged portions STIw+ of the lateral isolation regions STI are larger (in width) in the second direction Y than the nominal width STIw; and respectively the thickened portions ACTw− of the active regions ACT are smaller (in width) in the second direction Y than the nominal width ACTw.

FIGS. 3A, 3B, 3C and 3D illustrate the memory plane during the start of a step of etching GRTR a trench extending in depth in the substrate SUB.

FIG. 3A illustrates a plan view of the front face FA of the substrate SUB.

FIG. 3B illustrates a view in cross section in the plane BB of FIG. 3A (identical to the plane BB of FIG. 2A).

FIG. 3C illustrates a view in cross section in the plane CC of FIG. 3A (identical to the plane CC of FIG. 2A).

FIG. 3D illustrates a view in cross section in the plane DD of FIG. 3A (identical to the plane DD of FIG. 2A).

The etching GRTR of the trench TR is positioned so as to extend in length in the second direction Y and to pass, perpendicularly to its length, through a succession of widths of lateral isolation regions STI and of active regions ACT.

Thus, the etching of the trench GRTR passes vertically through said enlarged portions STIw+ of the lateral isolation regions STI and said thinned portions ACTw− of the active regions ACT.

The technique of etching GRTR of the trench TR is typically a dry etching of the reactive ion type, for example using a Reactive Ion Etching (RIE). This type of etching conventionally has rapid dynamics in the dielectric material of the lateral isolation regions STI, typically of silicon oxide, than in the semiconductor material of the active regions ACT, typically made from monocrystalline silicon.

Consequently, at the moment when the etching GRTR reaches the bottom of the shallow isolation trenches STI, the parts located facing the position of the shallow isolation regions STI are more deeply etched than the parts located facing the position of the active regions ACT.

Thus, the bottom of the trench TR in the course of etching has a form having variations in depths with low portions at the location of the trench passing through the lateral isolation regions STI, and high portions at the location of the trench passing through the active regions ACT.

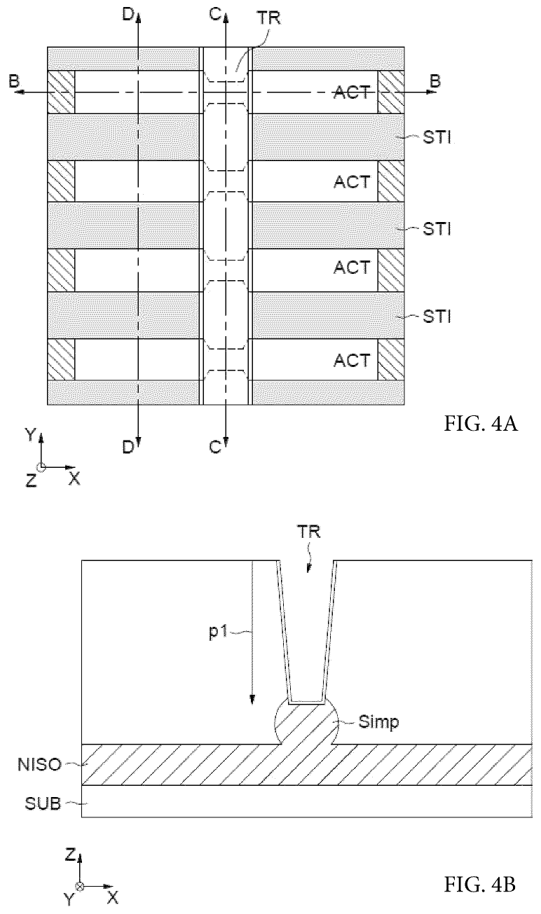

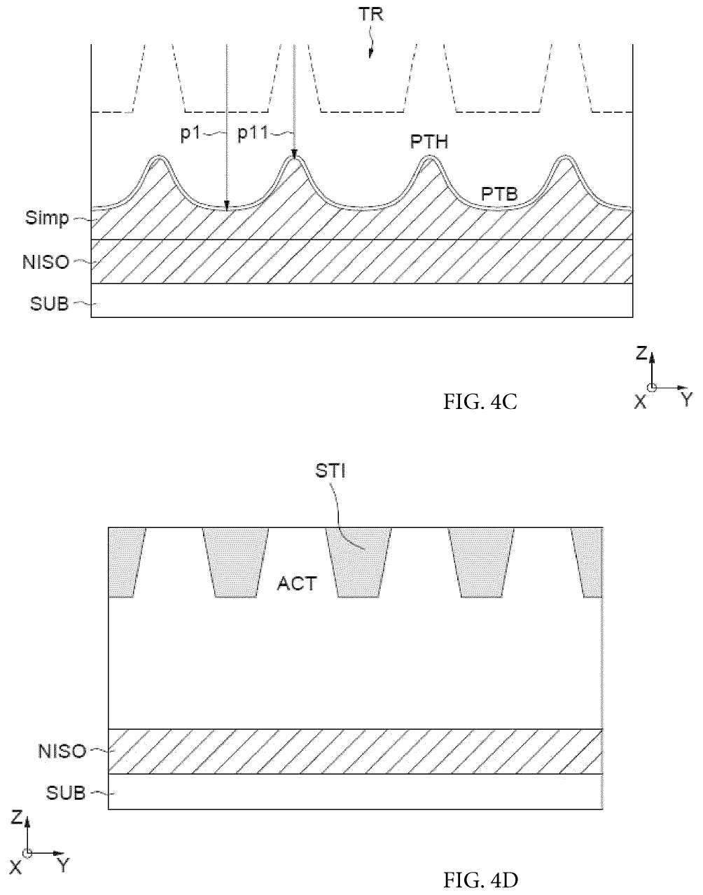

FIGS. 4A, 4B, 4C and 4D illustrate the memory plane at the end of the step of etching GRTR the trench TR extending in depth in the substrate SUB.

FIG. 4A illustrates a plan view of the front face FA of the substrate SUB.

FIG. 4B illustrates a view in cross section in the plane BB of FIG. 4A (identical to the plane BB of FIGS. 2A and 3A).

FIG. 4C illustrates a view in cross section in the plane CC of FIG. 4A (identical to the plane CC of FIGS. 2A and 3A).

FIG. 4D illustrates a view in cross section in the plane DD of FIG. 4A (identical to the plane DD of FIGS. 2A and 3A).

Between the state of the etching GRTR illustrated in FIGS. 3A-3D and the end of the etching, only the semiconductor material of the substrate (i.e., the monocrystalline silicon) is etched. Thus, the form of the bottom of the trench no longer substantially changes until the end of the etching GRTR, only the depth p1, p11 increases.

Thus, the bottom of the trench TR thus obtained has a form having variations in depths with low portions PTB, at the depth p1, facing the old lateral isolation regions STI before etching; and high portions PTH, at the depth p 11, facing the old active regions ACT before etching.

Moreover, a source region Simp, also referred to as source implant Simp, is implanted in the substrate SUB, from the bottom of the trench TR, between the bottom of the trench TR and the source plane NISO. The source implant Simp is thus designed to provide electrical continuity with the source plane NISO.

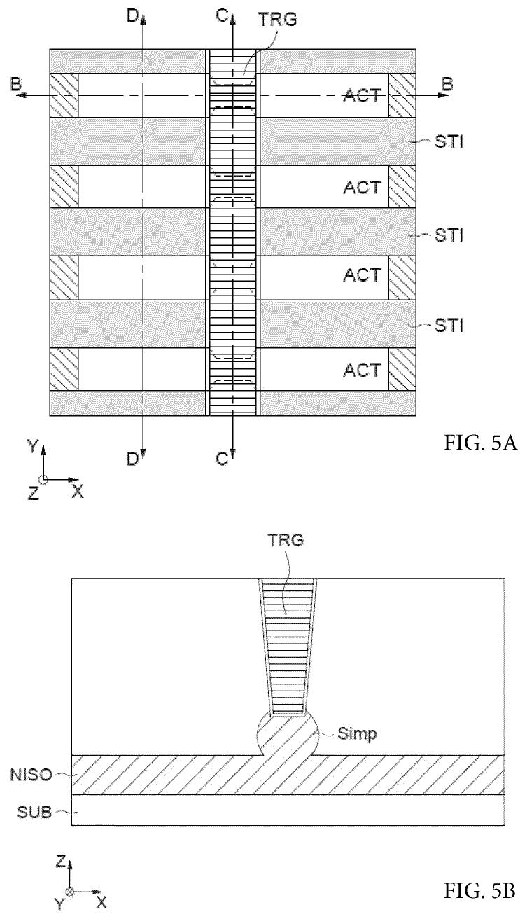

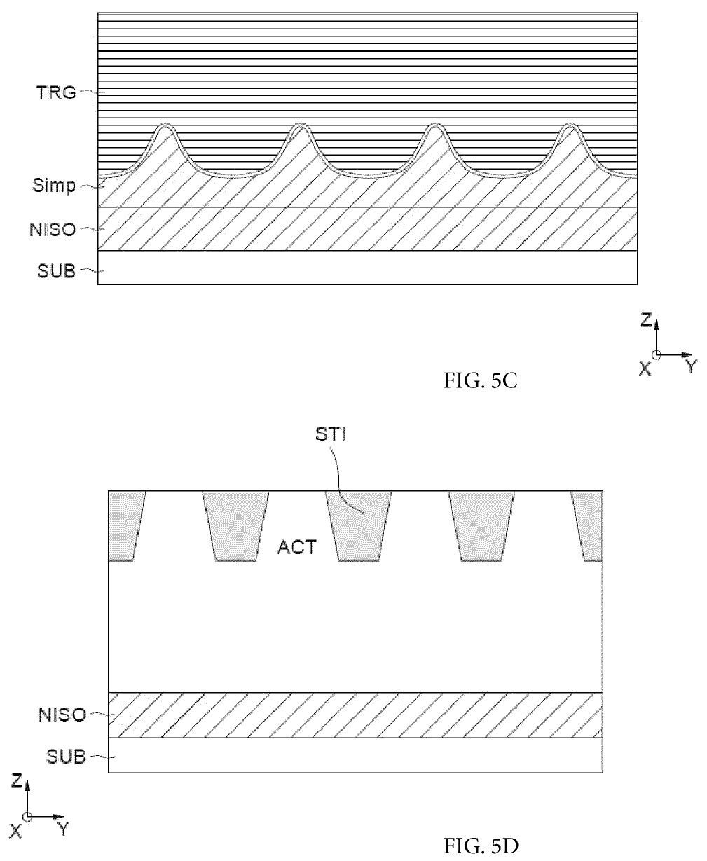

FIGS. 5A, 5B, 5C and 5D illustrate the memory plane at the end of a formation of a gate structure TRG in the trench TR extending in depth in the substrate SUB.

FIG. 5A illustrates a plan view of the front face FA of the substrate SUB.

FIG. 5B illustrates a view in cross section in the plane BB of FIG. 5A (identical to the plane BB in FIGS. 2A, 3A, 4A).

FIG. 5C illustrates a view in cross section in the plane CC of FIG. 5A (identical to the plane CC in FIGS. 2A, 3A, 4A).

FIG. 5D illustrates a view in cross section in the plane DD of FIG. 5A (identical to the plane DD in FIGS. 2A, 3A, 4A).

Firstly, a dielectric gate layer has been formed on the bottom and sides of the trench TR thus opened in the semiconductor substrate SUB, typically by oxidation.

Secondly, a conductive gate region has been formed in the volume of the trench, typically by depositing excess polycrystalline silicon overflowing over the front face FA, and a chemical-mechanical polishing step as far as the front face FA.

The gate structure TRG thus arranged in the trench TR includes the dielectric gate envelope on the sides and bottom of the trench, and the conductive gate region in the volume delimited by the envelope and the front face FA.

A source region Simp, NISO, and the vertical gate structure TRG, of a buried access transistor TA, for memory cells of the memory plane, has thus been formed in the trench TR.

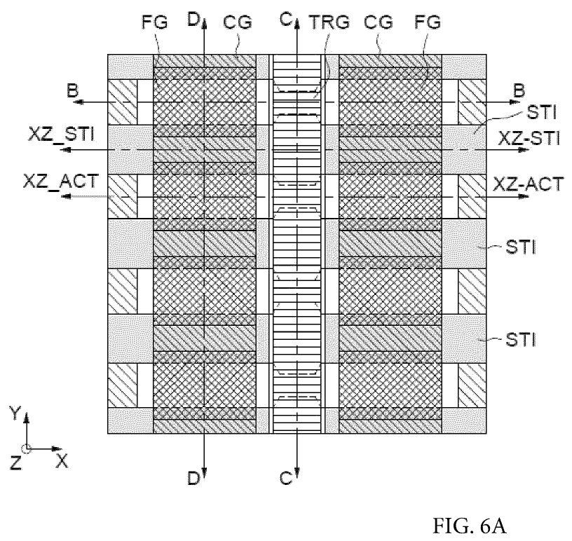

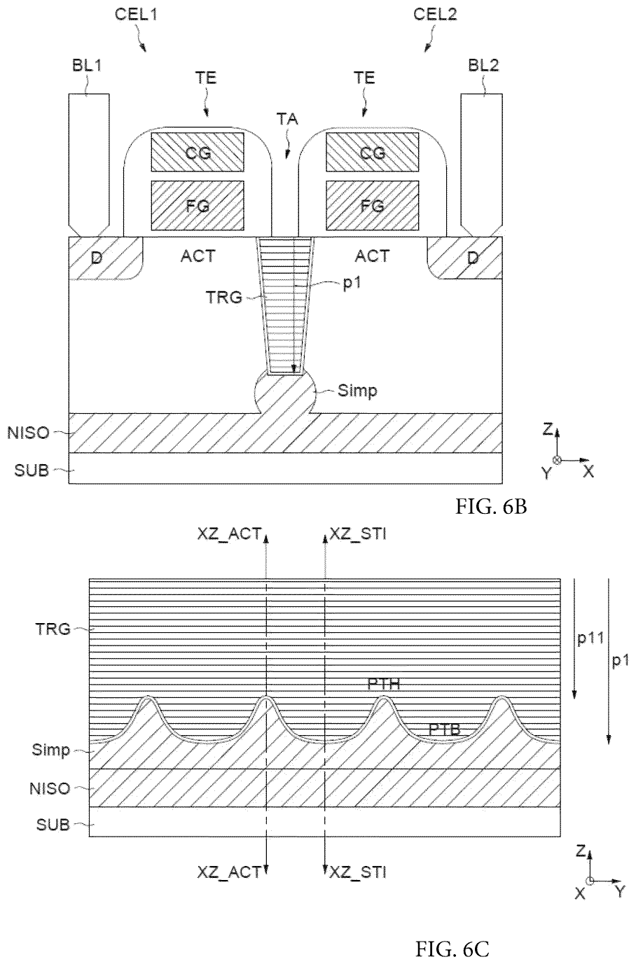

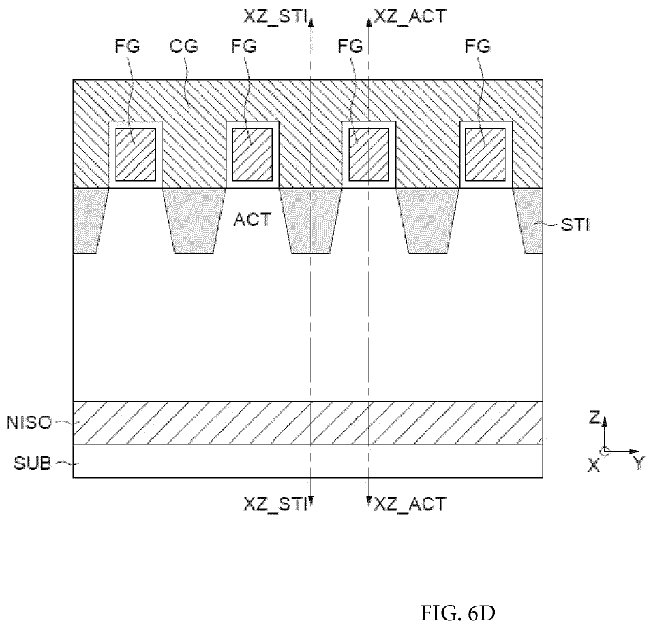

FIGS. 6A, 6B, 6C and 6D illustrate the memory plane at the end of steps finalizing the formation of memory cells CEL1, CEL2, in particular forming state transistors TE.

FIG. 6A illustrates a plan view of the front face FA of the substrate SUB.

FIG. 6B illustrates a view in cross section in the plane BB of FIG. 6A. The plane BB is identical to the plane BB of FIGS. 2A, 3A, 4A, 5A and passes through the gate regions CG, FG of the state transistors TE in length and the vertical gate region TRG in width.

FIG. 6C illustrates a view in cross section in the plane CC of FIG. 6A. The plane CC: is identical to the plane CC of FIGS. 2A, 3A, 4A, 5A and passes through the vertical gate region in length.

FIG. 6D illustrates a view in cross section in the plane DD of FIG. 6A. The plane DD is identical to the plane DD of FIGS. 2A, 3A, 4A, 5A and passes through the gate regions of the state transistors in width.

The steps completing the formation of the memory cells CEL1, CEL2 comprise the formation of state transistors TE including a floating gate FG surmounted by a control gate CG.

The conduction regions of the state transistor TE are implanted in the active regions ACT. The drain region D is connected to a respective bit line BL1, BL2, while the source region (not shown) of the state transistor TE is also the drain region of the access transistor TA, and makes the connection in series between the state transistor TE and the access transistor TA.

The bit lines BL1, BL2 are, for example, formed in a metal level extending above the memory plane in the first direction X.

The control gates CG can be produced so as to extend in the second direction Y, being able to form control gate lines used for selectively accessing the memory cells, belonging to one and the same group called a row.

The access transistor TA is also produced so as to extend in the second direction Y, and can form a word line used for selectively accessing the memory cells, belonging to one and the same group called a memory word.

The floating gates FG are formed so as to cover the active regions ACT of nominal width ACTw, particular to each memory cell CEL1, CEL2, on either side of the vertical gate TRG in the direction of the first direction X.

In particular, the interface between each floating gate FG and the underlying active region ACT is designed to implement injections of charges by “tunnel effect” through a tunnel oxide layer, typically by Fowler-Nordheim effect, and/or by injecting hot carriers resulting from impact ionizations.

The reliability and the performance with regard to multiple cycling of the memory cells CEL1, CEL2 are in particular determined by the width of the tunnel-effect injection interface (i.e., by the nominal width ACTw of the active regions ACT). The greater the nominal width ACTw of the active regions ACT, the greater the reliability of the memory cells.

Thus, it will be possible to make provision for forming the active regions ACT enlarged with respect to the floating gates FG (i.e., with a width ACTw (here referred to as the nominal width) greater than the conventional nominal widths of active regions).

This is because it is possible at the same time to improve the reliability of the memory cells CEL1, CEL2, by enlarging the active regions ACT with respect to the tunnel-injection zones; without giving rise to the problem relating to the resistance of the access transistor TA, because the active regions ACT include thinned portions ACTw− at the location of the etching of the trench TR of the access transistor TA.

In practice, a compromise between increasing the nominal width ACTw and reducing the width of the thinned portions ACTw− will be found, according to the design possibilities and drawings.

Moreover, from the point of view of the end device obtained by the method described above in relation to FIGS. 2A-D to 6A-D, the bottom of the trench TR containing the vertical gate TRG has a form having variations in depth with low portions PTB at a depth p1, and high portions HTB at a depth p11. The variations in depth p1-p11 have for example an amplitude greater than 50 nm.

The low portions PTB are located at the position of the trench TR that passes through the lateral isolation regions STI, such as at the intersection between the trench TR (extending in the second direction Y) and the lateral isolation regions STI (extending in the first direction X).

The high portions PTH are located at the position of the trench TR that passes through the active regions ACT, such as at the intersection between the trench TR (extending in the second direction Y) and the active regions ACT (extending in the first direction X).

In other words, this structure can also be defined geometrically in that the low portions PTB are located in planes XZ_STI directed by the vertical direction Z in the first direction X and at a position passing through the lateral isolation regions STI (in the length X); and in that the high portions PTH are located in planes XZ_ACT directed by the vertical direction Z and the first direction X and passing through the active regions ACT.

In the view in cross section of the plane CC, which is along the second direction Y, the form of the bottom of the trench has a substantially hypotrochoidal appearance (i.e., with a shortened trochoid). A trochoid is a curve obtained by tracing the movement described by a point connected to a disc rolling without sliding on a straight line, a trochoid in which the point describing the curve is located on the circumference of the disc is called a cycloid, the point describing a shortened trochoid being located between the center of the center and the circumference of the circle (over the radius of the disc).

In summary, a description has been given of a non-volatile memory including a double width of active regions, with a width ACTw wider in the tunnel-injection zones, and a width ACTw-narrower at the point of the trench TR of the access transistor TA.

This configuration greatly improves the compromise between the cycling performance and the problem of stoppage of the etching of the shallow isolation trenches STI, with an improvement in the uniformity of the depth of the shallow isolation trenches STI; without loss of density of the design (referred to in the art as the pitch density); without recourse to any modification of the method of manufacturing the shallow isolation trenches STI; and compatible with a reduction in scale of a potential technological development.

1. A method for manufacturing an integrated circuit, comprising:
forming lateral isolation regions delimiting active regions in a semiconductor substrate; and
etching a trench extending vertically in depth in the semiconductor substrate through said lateral isolation regions and said active regions;
wherein forming the lateral isolation regions comprises forming the lateral isolation regions to have, at locations where said etching of the trench is to be performed, enlarged portions of the lateral isolation regions which delimit thinned portions of the active regions.

2. The method according to claim 1, wherein forming the lateral isolation regions delimits the active regions extending in length in a first direction while said trench extends in length in a second direction perpendicular to the first direction, said enlarged portions of the lateral isolation regions and said thinned portions of the active regions being larger and smaller, respectively, in width in the second direction at the location of the etching of the trench than outside the location of the etching of the trench.

3. The method according to claim 1, wherein forming the lateral isolation regions comprises: producing a volume of dielectric material in the semiconductor substrate; wherein the active regions of the semiconductor substrate are produced from monocrystalline semiconductor material; and wherein dynamics of the etching of the trench are faster in the dielectric material than in the monocrystalline semiconductor material.

4. The method according to claim 1, further comprising:
forming a gate of a buried access transistor with vertical gate in said trench etched in depth in the semiconductor substrate; and
forming a stack of a floating gate and a control gate of a state transistor at least partly covering said active regions in the vicinity of the trench.

5. An integrated circuit, comprising:
a semiconductor substrate;
lateral isolation regions delimiting active regions in the semiconductor substrate; and
a component arranged in a trench extending vertically in depth in the semiconductor substrate through said lateral isolation regions and said active regions;
wherein a bottom of the trench has a form having variations in depth with lower portions facing the location of the trench that passes through the lateral isolation regions, and higher portions facing the location of the trench that passes through the active regions, said variations in depth due to the lateral isolation regions having, at locations of said trench, enlarged portions of the lateral isolation regions which delimit thinned portions of the active regions.

6. The integrated circuit according to claim 5, wherein the variations in depth have an amplitude greater than 50 nm.

7. The integrated circuit according to claim 5, wherein the lateral isolation regions delimit the active regions extending in length in a first direction while said trench extends in length in a second direction perpendicular to the first direction, the variations in depth in the bottom of the trench having successive alternations in the direction of the second direction.

8. The integrated circuit according to claim 7, wherein said lower portions are located in planes directed by the vertical direction and the first direction and passing through the lateral isolation regions, and said higher portions are located in planes directed by the vertical direction and the first direction and passing through the active regions.

9. The integrated circuit according to claim 5, further including:
a buried access transistor with vertical gate, the vertical gate being the component arranged in said trench; and
a state transistor including a stack of a floating gate and of a control gate at least partly covering said active regions in the vicinity of the trench.

10. The integrated circuit according to claim 5, wherein the bottom of the trench has a substantially hypotrochoidal appearance.

11. A semiconductor device, comprising:
a semiconductor substrate; and
lateral isolation regions delimiting active regions in a semiconductor substrate;
wherein the lateral isolation regions have enlarged portions of the lateral isolation regions which delimit thinned portions of the active regions.

12. The semiconductor device according to claim 11, wherein the enlarged portions of the lateral isolation regions are provided at locations where a trench is to be formed extending in depth into the semiconductor substrate through the enlarged portions of the lateral isolation regions and the thinned portions of the active regions.
